(19) United States
(12) Patent Application Publication
(10) Pub. No.: US 2008/0239671 A1
(43) Pub. Date: Oct. 2, 2008

(54) Semiconductor Element Mounting Substrate, Semiconductor Module, And Electric Vehicle

(75) Inventors: Atsushi Amano, Saitama (JP); Keisuke Urushihara, Saitama (JP); Kazuo Kimura, Tochigi (JP)

Correspondence Address: OBLON, SPIVAK, MCCLELLAND MAIER & NEUSTADT, P.C., 1940 DUKE STREET, ALEXANDRIA, VA, 22314, US

(73) Assignees: HONDA GIKEN KOGYO KABUSHIKI KAISHA, MITATIO-KU TOKYO JAPAN (JP); SHOWA DENKO K.K., MINATO-KU TOKYO JAPAN (JP)

(21) Appl. No.: 11/547,851

(22) PCT Filed: Apr. 6, 2005
(86) PCT No.: PCT/JP05/07114

§ 371 Date: Apr. 22, 2008

Related U.S. Application Data
(60) Provisional application No. 60/561,529, filed on Apr. 13, 2004.

(30) Foreign Application Priority Data
Apr. 6, 2004 (JP) 2004-112205
Dec. 13, 2004 (JP) 2004-360075

(51) Int. Cl. H05K 7/20

(52) U.S. Cl. 361/699; 361/702

(57) ABSTRACT

A semiconductor element mounting substrate excellent in cooling performance and simple in structure is provided. The semiconductor element mounting substrate is a substrate 1B for mounting a semiconductor element 2, and has an insulating layer 3 and a conducting layer 4 for attaching a semiconductor element 2 on one surface of the insulating layer 3. To the other surface of the insulating layer 3, a heat releasing device 5 is directly attached. The heat releasing device 5 is preferably a liquid-cooling type cooling plate 7 having a plurality of fine passage 7a for cooling fluid. The insulating layer is preferably a composite member that an insulating cloth is impregnated with insulating resin or insulating resin composite in which thermally conductive filler is added to insulating resin.

This application claims priority under 35 U.S.C. §119 to Japanese Patent Application No. 2004-112205 filed on Apr. 6, 2004, Japanese Patent Application No. 2004-360075 filed on Dec. 13, 2004 and U.S. Provisional Application No. 60/561,529 filed on Apr. 13, 2004, the entire disclosures of which are incorporated herein by reference in their entireties.

### CROSS REFERENCE TO RELATED APPLICATIONS

This application is an application filed under 35 U.S.C. §111(a) claiming the benefit pursuant to 35 U.S.C. §119(e)(1) of the filing date of U.S. Provisional Application No. 60/561,529 filed on Apr. 13, 2004, pursuant to 35 U.S.C. §111(b).

### TECHNICAL FIELD

The present invention relates to a semiconductor element mounting substrate, especially to a semiconductor element mounting substrate having cooling performance.

In this disclosure including claims, the wording of “aluminum” denotes aluminum and its alloy, and the wording of “copper” denotes copper and its alloy.

### BACKGROUND ART

The following description sets forth the inventor's knowledge of related art and problems therein and should not be construed as an admission of knowledge in the prior art.

A semiconductor element, such as a power semiconductor element, generates heat when applying current, and tends to increase the amount of heat generation in accordance with the recent increasing capacity. Since the heat generation has a substantial influence on the reliability and the life of the semiconductor element, it is required to suppress the temperature rise of the semiconductor element and its vicinity by providing a heat releasing portion to a module on which the semiconductor element is mounted. On the other hand, the semiconductor module has been required to be small in size because of the tendency of reduction in size and weight of various electronic products equipped with a semiconductor module.

FIG. 10 shows an example of a semiconductor module 50 in which a semiconductor element 52 is mounted on a semiconductor element mounting substrate 51, and an example of a heat releasing device 60 on which the aforementioned semiconductor module 50 is mounted.

In the semiconductor module 50, the semiconductor element mounting substrate 51 includes a metal plate 53 of copper or aluminum, an insulating layer 54 laminated on the metal plate and a conducting layer 55 of a copper foil or aluminum foil laminated on the insulating layer. The metal plate 53, the insulating layer 54 and the conducting layer 55 are integrally secured. The semiconductor element 52 is mounted on the conducting layer 55 of the substrate 51 via a soldering layer 56. To the metal plate side 53 of the substrate 51, the heat releasing device 60 is attached via heat-conducting grease 57 with bolts (not shown). In this illustrated example, a heat sink with comb-shaped fins is used as the heat releasing device 60.

Another semiconductor element mounting substrate having cooling function in which a substrate and a heat releasing device are integrally secured has been proposed (see Japanese Patent No. 3452011 [Patent document 1] and Japanese Unexamined Laid-open Patent Publication No. 2003-60136 [Patent Document 2]).

The semiconductor element mounting substrate described in the Patent Document 1 includes a ceramic insulation board, a metal layer secured to the surface of the insulation board and a heat releasing plate, wherein the metal layer and the heat releasing plate are integrally metal-jointed by a heat treatment.

The semiconductor element mounting substrate described in the Patent Document 2 includes an insulating substrate of ceramics or resin and a heat releasing member integrally secured to the substrate via a joining layer of brazing materials or adhesives.

According to the structure shown in FIG. 10, however, depending on the flatness and/or the surface roughness of the surface for attaching the semiconductor module 50 and the heat releasing device 60, large thermal resistance generates at the portion 57 of the heat conducting grease, which may result in deteriorated heat release performance. If sufficient heat release performance cannot be obtained, the heat releasing surface area of the heat releasing device must be increased to cope with the increasing heat generation amount, which contradicts the miniaturization of semiconductor modules. Moreover, this increases the number of assembly steps.

In the semiconductor element mounting substrate described in the Patent Document 1, although the structure is simple since no metal plate 53 as shown in FIG. 10 is required, a metal layer for joining to the ceramic insulation board and the metal heat releasing plate are required. Moreover, before joining the heat releasing plate to the ceramic insulation board, it is required to braze the metal layer to the ceramic insulation board in advance. For this reason, further simplification in structure and manufacturing step is required.

Also in the semiconductor element mounting substrate described in the Patent Document 2, although the structure is simple since no metal plate 53 as shown in FIG. 10 is required, the adhesive layer for joining the insulating substrate and the heat releasing member are required. In addition, since adhesive is used as the adhesive layer, the heat release capability declines due to the deteriorated thermal conductivity.

The description herein of advantages and disadvantages of various features, embodiments, methods, and apparatus disclosed in other publications is in no way intended to limit the present invention. Indeed, certain features of the invention may be capable of overcoming certain disadvantages, while still retaining some or all of the features, embodiments, methods, and apparatus disclosed therein.

Other objects and advantages of the present invention will be apparent from the following preferred embodiments.

### DISCLOSURE OF INVENTION

The preferred embodiments of the present invention have been developed in view of the above-mentioned and/or other problems in the related art. The preferred embodiments of the present invention can significantly improve upon existing methods and/or apparatuses.

The present invention was made in view of the aforementioned problems, and aims to provide a semiconductor element mounting substrate simple in structure and excellent in cooling performance, a semiconductor module using the semiconductor element mounting substrate, and an electric vehicle equipped with the semiconductor module.

To attain the aforementioned objects, the semiconductor element mounting substrate according to the present invention has the following structure [1] to [13].

[1] A semiconductor element mounting substrate, comprising:

an insulating layer;

a conductive layer for attaching a semiconductor element, the conductive layer being formed on one surface of the insulating layer; and

a heat releasing device directly secured to the other surface of the insulating layer.

[2] The semiconductor element mounting substrate as recited in the aforementioned Item 1, wherein the heat releasing device is a liquid-cooling type cooling plate having a plurality of fine passages through which cooling fluid passes.

[3] The semiconductor element mounting substrate as recited in the aforementioned Item 2,

wherein the liquid-cooling type cooling plate is provided with at least one flat multi-bored tube having fine passages for the cooling fluid, a case main body having two header forming dented portions disposed apart from each other, a tube accommodating dented portion for accommodating the tube, and a cover plate to be disposed on the case main body,

wherein the multi-bored tube is pinched by and between the case main body and the cover plate in a state in which the cover plate is disposed on the case main body with the multi-bored tube accommodated in the tube accommodating dented portion in communication with the header forming dented portions, and

wherein openings of both the header forming dented portions are closed by the cover plate, thereby forming two header portions, and

wherein the case main body, the multi-bored tube and the cover plate are integrally secured in a state in which leakage of the cooling fluid passing through the header portions is prevented.

[4] The semiconductor element mounting substrate as recited in the aforementioned Item 3, wherein the liquid-cooling type cooling plate is further provided with a first connecting member to be connected to a cooling fluid inlet tube and a second connecting member to be connected to a cooling fluid outlet tube, and wherein the first connecting member is connected to one of the header portions and the second connecting member is connected to the other of the header portions.

[5] The semiconductor element mounting substrate as recited in the aforementioned Item 2, wherein an equivalent diameter of the fine passage of the liquid-cooling type cooling plate is set so as to fall within the range of 0.05 to 1.7 mm.

[6] The semiconductor element mounting substrate as recited in the aforementioned Item 1, wherein the insulating layer is made of insulating resin.

[7] The semiconductor element mounting substrate as recited in the aforementioned Item 1, wherein the insulating layer is made of insulating resin composite in which thermally conductive filler is added to insulating resin.

[8] The semiconductor element mounting substrate as recited in the aforementioned Item 1, wherein the insulating layer is a composite member that an insulating cloth is impregnated with insulating resin or insulating resin composite in which thermally conductive filler is added to insulating resin.

[9] The semiconductor element mounting substrate as recited in the aforementioned Item 6, wherein the insulating resin is at least one of epoxy resin and polyimide resin.

[10] The semiconductor element mounting substrate as recited in the aforementioned Item 7, wherein the insulating resin is at least one of epoxy resin and polyimide resin.

[11] The semiconductor element mounting substrate as recited in the aforementioned Item 8, wherein the insulating resin is at least one of epoxy resin and polyimide resin.

[12] The semiconductor element mounting substrate as recited in the aforementioned Item 7 or 8, wherein the thermally conductive filler is at least one of SiO₂, Al₂O₃, BeO, MgO, Si₃N₄ and BN.

[13] The semiconductor element mounting substrate as recited in the aforementioned Item 7 or 8, wherein a content of the thermally conductive filler in the insulating resin composite is 40 to 90 Vol %.

[14] A semiconductor module, comprising:

a semiconductor element mounting substrate for mounting semiconductor elements, wherein the semiconductor element mounting substrate includes an insulating layer, a conductive layer for attaching a semiconductor element, the conductive layer being formed on one surface of the insulating layer, and a heat releasing device directly secured to the other surface of the insulating layer; and

a semiconductor element attached to the conductive layer.

[15] The semiconductor module as recited in the aforementioned Item 14, wherein the heat releasing device is a liquid-cooling type cooling plate having a plurality of fine passages for cooling fluid.

[16] The semiconductor module as recited in the aforementioned Item 14,

wherein the liquid-cooling type cooling plate is provided with at least one flat multi-bored tube having fine passages for the cooling fluid, a case main body having two header forming dented portions disposed apart from each other, a tube accommodating dented portion for accommodating the tube, and a cover plate to be disposed on the case main body,

wherein the multi-bored tube is pinched by and between the case main body and the cover plate in a state in which the cover plate is disposed on the case main body with the multi-bored tube accommodated in the tube accommodating dented portion in communication with the header forming dented portions, and

wherein openings of both the header forming dented portions are closed by the cover plate, thereby forming two header portions, and

wherein the case main body, the multi-bored tube and the cover plate are integrally secured in a state in which leakage of the cooling fluid passing through the header portions is prevented.

[17] An electric vehicle equipped with a semiconductor module, wherein the semiconductor module includes a semiconductor element mounting substrate for mounting semiconductor elements, the semiconductor element mounting substrate being provided with an insulating layer, a conductive layer for attaching a semiconductor element, the conductive layer being formed on one surface of the insulating layer, and a heat releasing device directly secured to the other surface of the insulating layer, and a semiconductor element attached to the conductive layer.

[18] The electric vehicle as recited in the aforementioned Item 17, wherein the heat releasing device of the semiconductor element mounting substrate is a liquid-cooling type cooling plate having a plurality of fine passages for cooling fluid.

[19] The electric vehicle as recited in the aforementioned Item 18, wherein the electric vehicle is further equipped with a radiator, wherein cooling liquid cooled by the radiator is introduced into the cooling plate, and the cooling liquid flowed out of the liquid-cooling type cooling plate is cooled by the radiator.

### EFFECTS OF THE INVENTION

In the semiconductor element mounting substrate according to the aforementioned Item [1], since the insulating layer is directly joined to the heat releasing device, the thermal resistance is small and excellent cooling performance can be demonstrated. Moreover, it is simple in structure, and therefore the manufacture steps can be simplified.

According to the semiconductor element mounting substrate of the invention as recited in the aforementioned Item [2], especially excellent cooling performance can be secured.

According to the semiconductor element mounting substrate of the invention as recited in the aforementioned Item [3], more excellent cooling performance can be secured, and it is excellent in strength.

According to the semiconductor element mounting substrate of the invention as recited in the aforementioned Item [4], the joining of the cooling fluid inlet and outlet tubes to the substrate can be performed easily.

According to the semiconductor element mounting substrate of the invention as recited in the aforementioned Item [5], especially excellent cooling performance can be secured.

According to the semiconductor element mounting substrate of the invention as recited in the aforementioned Item [6], excellent cooling performance can be secured since the adhesiveness of the insulating layer and the heat releasing device is high. Furthermore, since the insulating layer is more hard to crack than a ceramic insulating layer, it is possible to manufacture a larger substrate.

According to the semiconductor element mounting substrate of the invention as recited in the aforementioned Item [7], since the adhesiveness of the insulating layer and the heat releasing device is high and the thermal conductivity of the insulating layer is improved by the thermally conductive filler, excellent cooling performance can be secured.

According to the semiconductor element mounting substrate of the invention as recited in the aforementioned Item [8], the insulating layer is high in strength, and the dimensional change, curve and torsion over the time can be restrained.

According to the semiconductor element mounting substrate of each invention as recited in the aforementioned Items [9] to [11], an insulating layer which is excellent in heat resistance and restrained in deformation due to thermal expansion can be formed.

According to the semiconductor element mounting substrate of the invention as recited in the aforementioned Item [12], an insulating layer especially high in thermal conductivity can be formed.

According to the semiconductor element mounting substrate of the invention as recited in the aforementioned Item [13], an insulating layer especially high in thermal conductivity can be formed.

According to the semiconductor module of the invention as recited in the aforementioned Item [14], the semiconductor element can be cooled assuredly, and the high reliability of the operation can be secured for a long period of time.

According to the semiconductor module of the invention as recited in the aforementioned Item [15], especially excellent cooling performance can be secured.

According to the semiconductor module of the invention as recited in the aforementioned Item [16], more excellent cooling performance can be secured and it is excellent in strength.

According to the electric vehicle of the invention as recited in the aforementioned Item [17], the semiconductor element for electric vehicles can be cooled assuredly.

According to the electric vehicle of the invention as recited in the aforementioned Item [18], the semiconductor element for electric vehicles can be cooled more assuredly.

According to the electric vehicle of the invention as recited in the aforementioned Item [19], the cooling fluid circulates through the cooling plate and the radiator, and therefore cooling of the semiconductor element can be performed easily.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF DRAWINGS

FIG. 1 is a schematic cross sectional view showing a semiconductor element mounting substrate and a semiconductor module according to an embodiment of the present invention.

FIG. 2 is a figure (graph) showing the relation between the equivalent diameter of the fine passage of the tube and the thermal resistance in the liquid-cooling type cooling plate built in the semiconductor element mounting substrate shown in FIG. 1.

FIG. 3 is a perspective view showing a semiconductor element mounting substrate according to another embodiment of the present invention.

FIG. 4 is an exploded perspective view showing a liquid-cooling type cooling plate of the semiconductor element mounting substrate shown in FIG. 3.

FIG. 5 is a cross sectional view taken along the line X-X shown in FIG. 3.

FIG. 6 is a cross-sectional view taken along the line Y-Y shown in FIG. 3.

FIG. 7 is a cross-sectional view taken along the line Z-Z shown in FIG. 3.

FIG. 8 is a schematic plane view showing an electric vehicle mounting the semiconductor module in which the semiconductor element mounting substrate shown in FIG. 3 is mounted.

FIG. 9 is a schematic cross-sectional view showing a method of joining a conducting layer, an insulating layer and a heat releasing device.

FIG. 10 is a cross-sectional view showing a conventional semiconductor element mounting substrate and a semiconductor module in which the semiconductor element mounting substrate and a heat releasing device are assembled.

### BEST MODE FOR CARRYING OUT THE INVENTION

In the following paragraphs, some preferred embodiments of the invention will be described by way of example and not limitation. It should be understood based on this disclosure that various other modifications can be made by those in the art based on these illustrated embodiments.

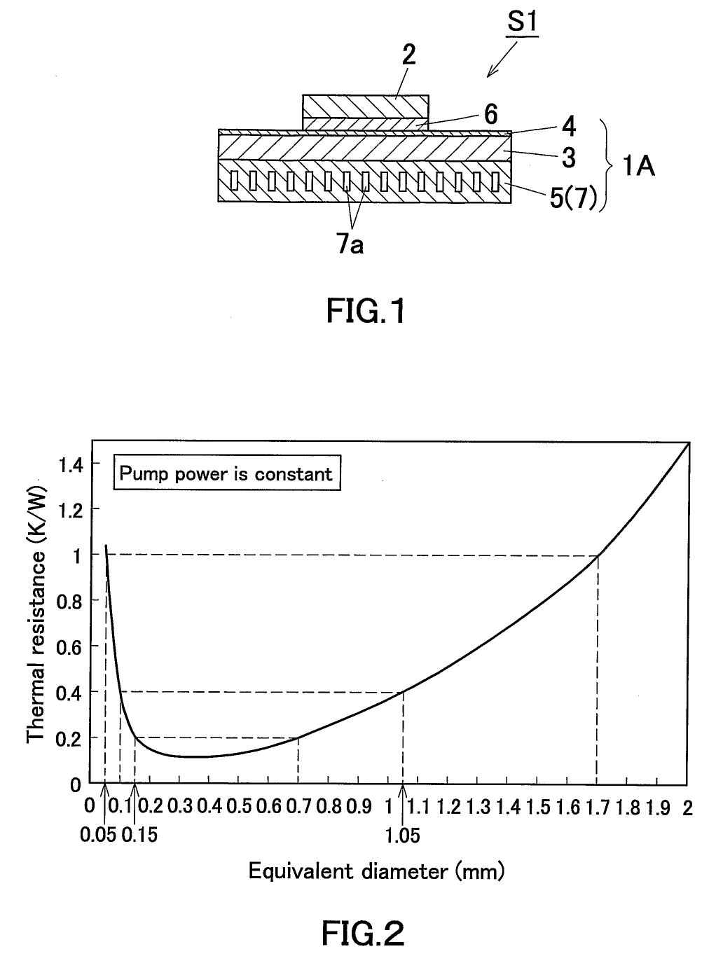

FIG. 1 shows a semiconductor module S1 in which a semiconductor element 2 is mounted on a semiconductor element mounting substrate 1A according to an embodiment of this invention.

The semiconductor element mounting substrate 1A is a substrate in which a conducting layer 4 is formed on one surface of an insulating layer 3, a heat releasing device 5 is directly joined to the other surface of the insulting layer 3 without intervening an adhesive layer, and these elements are integrally secured. The aforementioned semiconductor module S1 is a module in which a semiconductor element 2 is attached to the conducting layer 4 of the aforementioned semiconductor element mounting substrate 1A with, e.g., soldering agent. The means for attaching the semiconductor element 2 is not limited to a means using soldering agent, and can be any well-known means such as wax and paste.

The aforementioned conducting layer 4 is a layer of conductive material, such as a copper foil or an aluminum foil.

The insulating layer 3 is made of insulation material capable of directly joining the heat releasing device 5. Concretely, as the material of the insulating layer 3, three types of materials, i.e., insulating resin, an insulating resin composite in which thermally conductive filler is added to the aforementioned insulating resin, a composite member in which an insulating cloth is impregnated with the aforementioned insulating resin or insulating resin composite, can be recommended. Such resin based insulating layer is hard to crack as compared with ceramics, and therefore an insulating layer having a larger area can be manufactured.

As the aforementioned insulating resin, it is preferable to use resin excellent in heat resistance, small in coefficient of thermal expansion, and excellent in adhesiveness capable of closely adhering to a metal heat releasing device. Among other resins meeting such requirements, epoxy resin or polyimide resin can be recommended. Especially, epoxy resin can be recommended since it is excellent in adhesiveness to a copper member, small in hygroscopicity, and low in cost. Polyimide resin also can be recommended since it is excellent in chemical resistance and small in coefficient of thermal expansion in the thickness direction.

By using an insulating resin composition in which thermally conductive filler is added to the aforementioned insulating resin, the thermal conductivity of the insulating layer can be enhanced, resulting in enhanced heat release performance. It is preferable that the thermally conductive filler is an insulator of metal oxide or metal nitride high in temperature conductivity. Concretely, SiO₂, Al₂O₃, BeO, MgO, Si₃N₄ and BN can be exemplified. These thermally conductive fillers can be used independently or in combination. As the content of the thermally conductive filler in the resin composition increases, the thermal conductivity of the insulating layer 3 becomes higher, and the preferable content of the thermally conductive filler is 40 to 90 Vol %. If it is less than 40 Vol %, the thermal conductivity improvement effect becomes poor. On the other hand, if it exceeds 90 Vol %, adhesiveness to the heat releasing device deteriorates, resulting in deteriorated heat release performance. More preferable content is 60 to 80 Vol %. The preferable particle diameter of the thermally conductive filler is 10 to 40 μm.

As the aforementioned insulating layer 3, it is also preferable to use a composite member in which an insulating cloth is impregnated with the aforementioned insulating resin or insulating resin composite. The insulating cloth has effects of giving strength to the insulating layer 3 and preventing occurrence of dimensional change, curve, and/or torsion thereof with time due to the heat generated from the semiconductor element. As the insulating cloth, a nonwoven fabric or woven fabric made of inorganic fibers, such as glass fibers, can be recommended since inorganic fiber cloths are small in dimensional change, curve and torsion thereof as compared with papers and synthetic fiber cloths. Although insulating resin or insulating resin composite is impregnated in such an insulating cloth as mentioned above, it is not necessary that a cloth exists in the entire thickness direction of the insulating layer 3. For example, a part of the cloth can be impregnated with the insulating resin or insulating resin composite such that the resins are laminated in the cloth. It preferable that the insulating cloth is as thinner as possible since the insulating cloth interferes the heat conduction or heat release of the insulating layer 3.

In each insulating layer of the aforementioned three types, it is preferable that the thickness falls within the range of 0.01 to 0.5 mm.

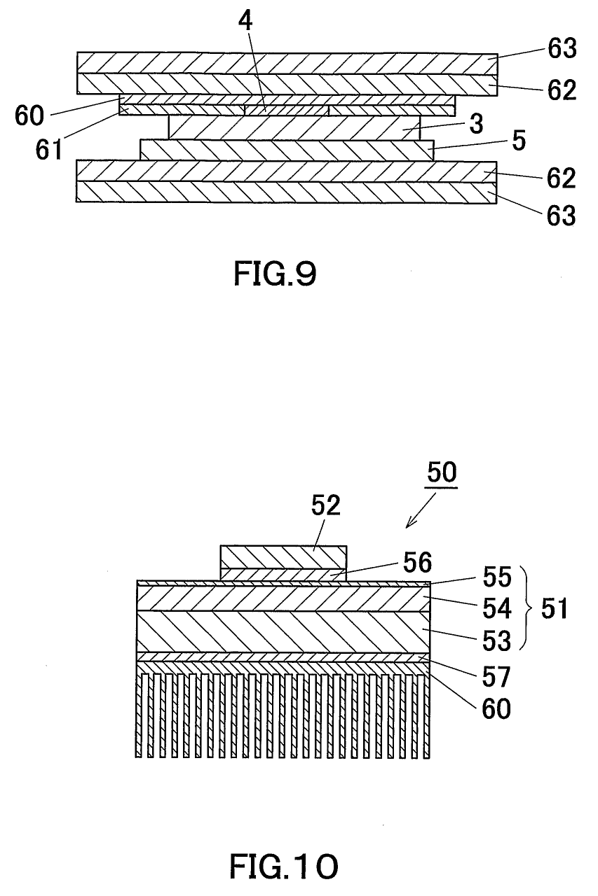

The heat releasing device 5 can be of any type so long as it can be directly joined to the insulating layer 3. As the heat releasing device, a heat releasing flat plate, a comb-shaped heat sink as illustrated in FIG. 10, or a heat tube of any types can be used regardless whether it is an air-cooling type or a liquid-cooling type. The structure in which the insulating layer 3 and the heat releasing device 5 are directly joined secures sufficient strength as a substrate. In other words, the strength deterioration due to the elimination of the metal plate 53 from the semiconductor substrate 51 shown in FIG. 10 can be sufficiently complemented by the joining of the heat releasing device 5.

The heat releasing device illustrated in FIG. 1 is an aluminum liquid-cooling type cooling plate 5 constituted by a flat multi-bored tube 7. Such a liquid-cooling type cooling plate 5 can be suitably used as a heat releasing device in the semiconductor element mounting substrate 1A since it is thin and excellent in heat releasing performance.

The aforementioned multi-bored tube 7 has a plurality of fine passages 7a each square in cross-section. This multi-bored tube 7 can be manufactured by, for example, extrusion or rolling. Such extruded tubes and rolled tubes are generally used in heat exchangers. By attaching header portions (not shown) or inlet/outlet pipes (not shown) for cooling fluid to both end openings of the fine passages 7a, a liquid-cooling type cooling plate is manufactured.

The cross-sectional shape of the fine passage 7a is not limited to a specific shape, and can be, for example, approximately circular, elliptic, astral or polygonal. Furthermore, the aforementioned plurality of fine passages 7a are independent each other, or not communicated with each other, but can be communicated with each other.

FIG. 2 is a graph showing the relation between the equivalent diameter of the fine passage 7a and the thermal resistance thereof in the aforementioned liquid-cooling type cooling plate 5 when the power of the cooling fluid pump is constant. The equivalent diameter “de” can be calculated by the formula “4A/p,” where “A” is the cross-sectional area of the fine passage 7a and “p” is the wet peripheral length of the fine passage 7a. Generally, although the absolute value of thermal resistance changes with the size of the cooling plate 5, the thermal resistance with respect to the equivalent diameter tends not to change with the size of the cooling plate 5 as shown in this figure.

As shown in FIG. 2, in cases where the equivalent diameter of the fine passage 7a of the multi-bored tube 7 is set to fall within the range of 0.05 to 1.7 mm, the thermal resistance becomes small and, therefore, high cooling performance can be demonstrated. The thermal resistance further decreases in cases where this equivalent diameter is set to fall within the range of 0.1 to 1.05 mm, and still further decreases in cases where this equivalent diameter is set to fall within the range of 0.15 to 0.7 mm, which can demonstrate higher cooling performance. Accordingly, it is preferable to set the average equivalent diameter so as to fall within the range of 0.05 to 1.7 mm, more preferably 0.1 to 1.05 mm, optimally 0.15 to 0.7 mm.

The joining of the conducting layer 4, the insulating layer 3 and the heat releasing device 5 can be performed by any known method such as hot pressing.

For example, in cases where thermosetting resin is used as the insulating resin constituting the insulating layer 3, the conducting layer 4, the insulating layer 3 and the heat releasing device 5 are disposed one on another and pinched from the upper and lower sides thereof with stainless steel plates, then heated with these members pressed via cushioning materials. This hot pressing causes hardening of the insulating layer 3 and joining of the insulating layer 3 to the heat releasing device 5 and the conducting layer 4, which results in integral joining of these members.

In cases where a conducting layer 4 is joined to a part of an insulating layer 3 as shown in FIG. 9, the joining can be performed using an alignment sheet 60 and a supporting plate 61. In detail, the conducting layer 4 is attached to the alignment sheet 60, and disposed on the insulating layer 3 with the supporting plate 61 having an opening corresponding to the conducting layer 4 put on the heat releasing device 5, and then these members are pinched with the stainless steel plates 62 and heated via the cushioning members 63 under pressure. This causes joining of the conducting layer 4 to the predetermined position of the insulating layer 3. Furthermore, in cases where a composite member made of an insulating resin composite or an insulating cloth is used as the insulating layer 3, a composition or a composite member having prescribed compositions is prepared in advance, and it is integrally joined by hot pressing in the same manner as mentioned above.

As shown in FIG. 1, the aforementioned liquid-cooling type cooling plate is directly joined to the insulating layer 3 with the multi-bored tube 7 exposed, but it can be replaced with a cooling member in which one or a plurality of multi-bored tubes are disposed in a casing.

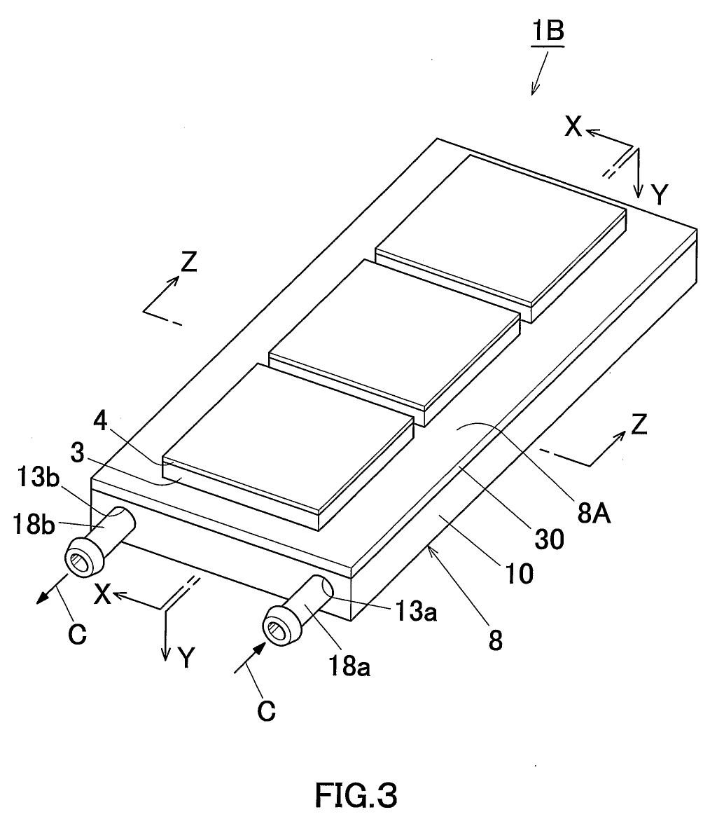

In the semiconductor element mounting substrate 1B shown in FIG. 3, a liquid-cooling type cooling plate 8 in which multi-bored tubes are embedded in a casing is employed. On each of plural portions of one side of the liquid-cooling type cooling plate 8, insulating layers 3 and conducting layers 4 are laminated.

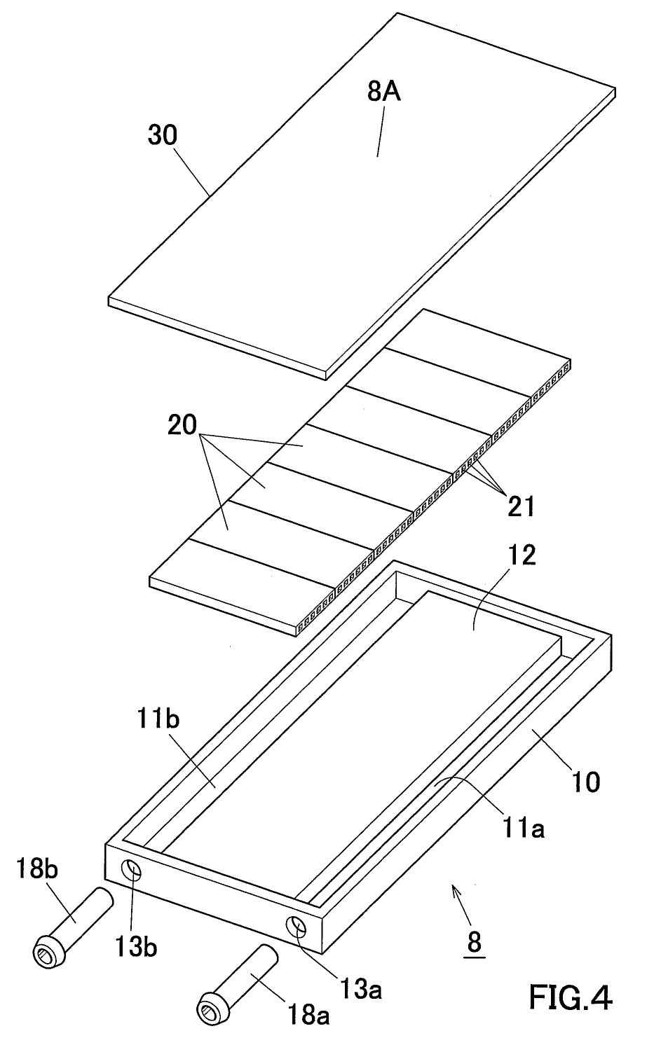

As shown in FIG. 4, the aforementioned liquid-cooling type cooling plate 8 is equipped with a case main body 10, a cover plate 30, a plurality of multi-bored tubes 20 each having a plurality of fine passages 21 for cooling fluid, a first connecting member 18a and a second connecting member 18b. As the material of the cooling plate, aluminum or copper having higher thermal conductivity can be recommended.

As shown in FIG. 4, the case main body 10 is formed into a square shape as seen from the above, and is provided with two header forming dented portions 11a and 11b disposed in parallel at the right and left sides of the central portion of the case main body 10. The case main body 10 is further provided with a tube accommodating dented portion 12 for accommodating the tubes 20 between both the header forming dented portions 11a and 11b. Each header forming dented portion 11a and 11b is formed approximately into a quadrangular cross-sectional shape. The depth of the tube accommodating dented portion 12 is set to have approximately the same size as the thickness of the tube 20. On the other hand, the depth of each header forming dented portion 11a and 11b is set to have a size larger than the depth of the tube accommodating dented portion 12. At one end surface of the case main body 10, a first connecting member insertion aperture 13a communicating with one end portion of one header forming dented portion 11a and a second connecting member insertion aperture 13b communicating with one end portion of the other header forming dented portion 11b are provided.

The shape and the size of the lower surface of the cover plate 30 are set to the same shape and size of the upper surface of the case main body 10. Therefore, in a state in which the cover plate 30 is disposed on the upper surface of the case main body 10, the openings of both the header forming dented portions 11a and 11b and the opening of the tube accommodating dented portion 12, which are formed on the upper surface of the case main body 30, are closed by the cover plate 30. As shown in FIG. 3, on the upper surface of the cover plate 30, the insulating layers 3 and the conducting layers 4 are to be attached. That is, in the liquid-cooling type cooling plate 8 according to this embodiment, the upper surface of the cover plate 30 functions as a cooling surface 8A. The cooling surface 8A of the cover plate 30 is formed to be a flat shape. Similarly, the lower (rear) surface of the cover plate 30 is formed to be a flat shape.

On the inner and upper surfaces of the case main body 10, brazing material is covered. Similarly, also on at least the lower surface of the cover plate 30, the external peripheral surface of the multi-bored tube 20 and the external peripheral surface of both the connecting members 18a and 18b, brazing material is covered.

Each multi-bored tube 20 is provided with a plurality of fine passages 21. Each fine passage 21 is a fine penetrated aperture having a square shape in cross-section. The manufacturing method of the multi-bored tube 20, the preferable cross-sectional shape of the fine passage 21 and the preferable equivalent diameter for demonstrating high cooling performance can be the same as those of the aforementioned multi-bored tube 7 and its fine passage 7a.

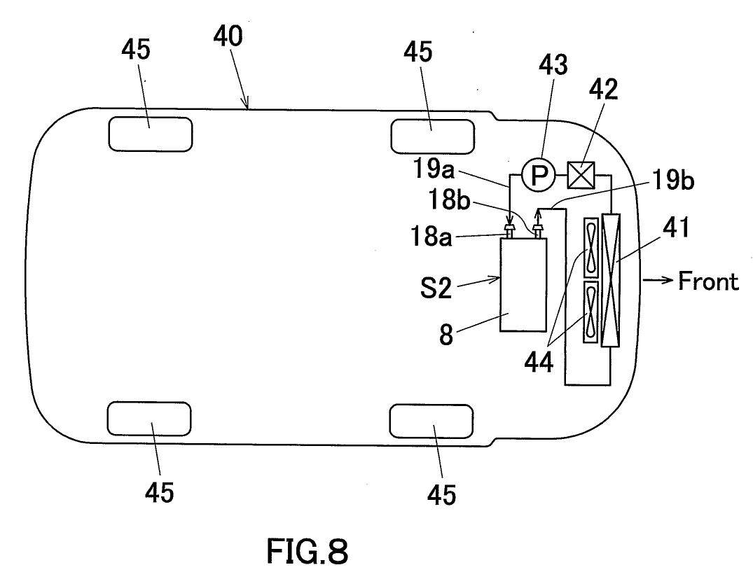

The first connecting member 18a and second connecting member 18b are formed into a short pipe with a connecting port at one end, respectively, as shown in FIG. 4. As shown in FIG. 8, the first connecting member 18a is to be connected to a cooling liquid inlet tube 19a in a liquidly sealed manner. On the other hand, the second connecting member 18b is to be connected to a cooling liquid outlet tube 19b in a liquidly sealed manner.

Now, the structure of the cooling plate 8 will be explained based on the manufacturing method.

As shown in FIGS. 4 to 7, a plurality of tubes 20 arranged in line along the widthwise direction are accommodated in the tube accommodating dented portion 12 of the case main body 10 with the tubes communicated with the header forming dented portions 11a and 11b. In this case, if necessary, brazing material can be disposed between the bottom surface of the tube accommodating dented portion 12 of the case main body 10 and the tubes 20.

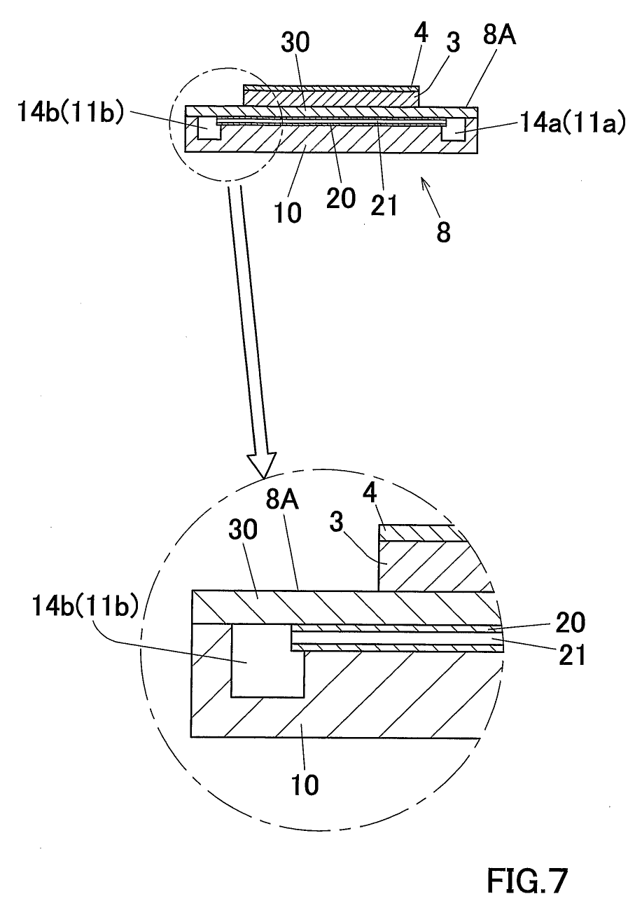

Thereafter, the cover plate 30 is disposed on the surface of the case main body 10 so as to cover the entire tubes 20. By disposing the cover plate 30 as mentioned above, the tubes 20 are disposed between the case main body 10 and the cover plate 30, and the openings of the header forming dented portions 11a and 11b of the case main body 10 are closed by the cover plate 30. As a result, as shown in FIG. 7, two header portions 14a and 14b are formed in the case main body 10. In the step of disposing the cover plate 30, brazing material can be disposed between the case main body 10 and the cover plate 30 and/or between the tubes 20 and the cover plate 30.

Before the step of disposing the cover plate 30, simultaneously with the step of disposing the cover plate 30, or after the step of disposing the cover plate 30, the first connecting member 18a and the second connecting member 18b are inserted into the corresponding insertion apertures 13a and 13b, respectively, so that the first connecting member 18a is connected to the first header forming dented portion 11a in liquid communication and the second connecting member 18b is connected to the second header forming dented portion 11b in liquid communication.

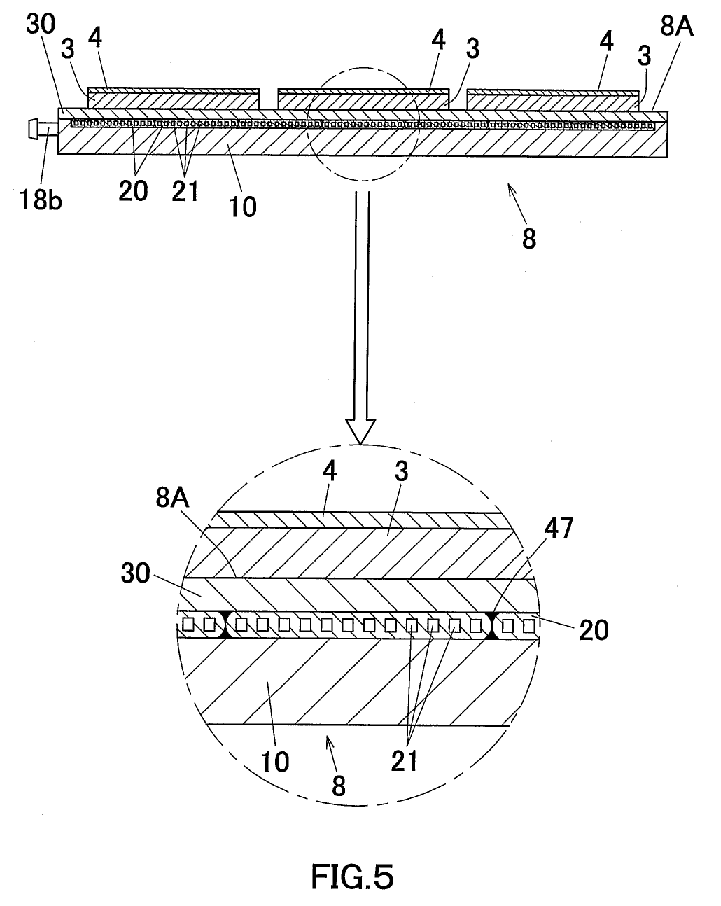

Thereafter, the cooling plate assembly assembled as mentioned above is introduced in a brazing furnace, so that the tubes 20, the cover plate 30, the first connecting member 18a, the second connecting member 18b are simultaneously brazed with each other. In this brazing step, the case main body 10 and the cover plate 30 are integrally jointed with each other in a liquidly sealed manner, or in a state in which the leakage of the cooling liquid C accommodated in each header portions 14a and 14b is prevented. Furthermore, the first connecting member 18a and the second connecting member 18b are secured in the corresponding insertion apertures 13a and 13b in a liquidly sealed manner. In FIG. 5, the reference numeral “47” denotes a fillet of the brazing material.

Through the aforementioned steps, the liquid-cooling type cooling plate 8 as shown in FIG. 3 is obtained. In the same manner as the aforementioned semiconductor element mounting substrate 1A, by forming an insulating layer 3 and a conducting layer 4 on the cooling surface 8A of this liquid-cooling type cooling plate 8, a semiconductor element mounting substrate 1B is manufactured. By furthermore attaching a semiconductor element on the conducting layer 4 of this semiconductor element mounting substrate 1B, a semiconductor module S2 (not illustrated) is manufactured.

In the liquid-cooling type cooling plate 8, since the multi-bored tubes 20 are accommodated in the predetermined dented portion 12 of the case main body 10, the deterioration of the flatness of the cooling surface 8A due to the heat for brazing the assembly and the deformation of the multi-bored tubes 21 can be prevented assuredly. Therefore, the flatness of the cooling surface 8A can be retained with a high degree of accuracy, which in turn enables efficient cooling of the semiconductor element 2 by enhancing the fitness to the insulating layer 3. Furthermore, the fine passage 21 can be held to have a predetermined shape and size, resulting in high cooling performance. Furthermore, since the tubes 20 are accommodated in a space formed by the case main body 10 and the cover plate 30 and brazed thereto, the cooling plate is high in mechanical strength. Moreover, since fillets are formed in gaps formed between the case main body 10 and the tube 20 and between the case main body 10 and the cover plate 30, the thermal conductivity is excellent, which enables excellent cooling performance.

Furthermore, since the liquid-cooling type cooling plate 8 is provided with the first connecting member 18a to be connected to the cooling liquid inlet pipe 19a and the second connecting member 18b to be connected to the cooling liquid outlet pipe 19b, the operation for joining the cooling liquid inlet pipe 19a and cooling liquid outlet pipe 19b to the liquid-cooling type cooling plate 8 can be performed easily.

In the semiconductor element mounting substrate according to the present invention, since the insulating layer and the heat releasing device are integrally secured, it is not necessary to attach a heat releasing device at another step, which simplifies the manufacturing steps. In addition, since the insulating layer and the heat releasing device are directly secured each other, the thermal resistance is small, resulting in excellent cooling performance.

The semiconductor element mounting substrate 1A and 1B and the semiconductor module S1 and S2 according to the present invention will be mounted to electronics products, such as electric vehicles and computers, to assuredly cool a semiconductor, which secures high operational reliability of the semiconductor over a long period of time. The cooling also extends the life of semiconductor element. As the semiconductor module, an IGBT module, an inverter, a converter, a semiconductor controlling element, a diode, a capacitor, a coil, light-emitting parts, a semiconductor device, a multichip module, a speaker, a CRT, a hard disk drive, a DVD drive, printer parts (e.g., thermal head), or a module to be mounted thereon can be exemplified. The wording of “electric vehicle” includes a hybrid vehicle. As a vehicle, a car, a motorcycle, a railroad vehicle can be exemplified.

As an example of the application of the aforementioned semiconductor module, an electric vehicle 40 mounting the aforementioned semiconductor module S2 will be explained with reference to FIG. 8.

In the electric motorcar 40, an existing radiator 41 for cooling cooling-liquid is mounted. This radiator 41 is disposed at the front portion of the electric motorcar 40. The reference numeral “44” denotes a fan for the radiator and the reference numeral “45” denotes a wheel.

To the first connecting member 18a of the liquid-cooling type cooling plate 8, a cooling liquid inlet tube 19a is connected in a liquidly sealed manner. On the other hand, to the second connecting member 18b of the cooling plate 8, a cooling liquid outlet tube 19b is connected in a liquidly sealed manner. The cooling liquid cooled in the radiator 41 is introduced into the cooling liquid inlet tube 19a. The cooling liquid flowed out of the cooling plate 8 is introduced into the cooling liquid outlet tube 19b. Thereafter, the cooling liquid is returned to the radiator 41.

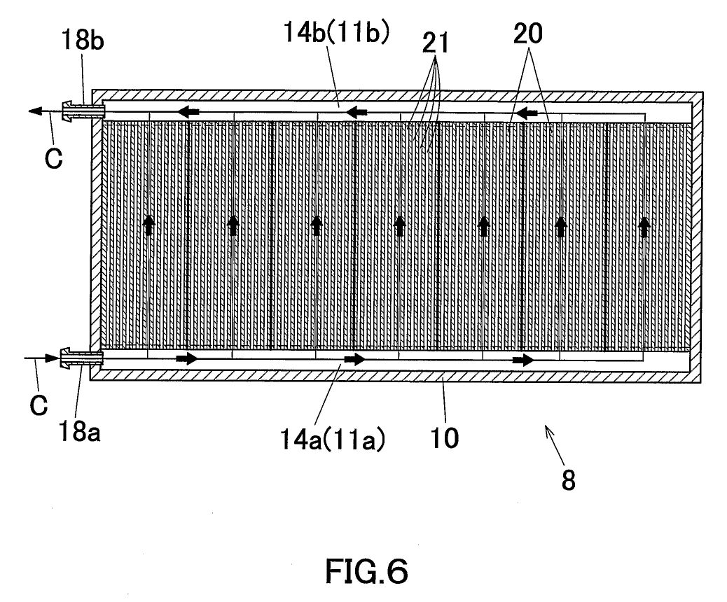

In this electric motorcar 40, the cooling liquid cooled by the radiator 41 is sent to the cooling plate 8 through the cooling liquid inlet tube 19a via the reserve tank (receiver tank) 42 with a pump 43. Thus, as shown in FIG. 6, this cooling liquid C is introduced into the first header portion 14a through the first connecting member 18a of the cooling plate 8. The introduced cooling liquid C diverges in plural paths at the first header portion 14a and passes through the fine passages of each tube 20. During passing through the tubes 2, the cooling liquid C cools the semiconductor element 2 by taking the heat therefrom. The cooling liquid C flows into the second header portion 14b to be merged therein. Then, the merged cooling liquid C flows out of the second connecting member 18b. Thereafter, the cooling liquid C is introduced into the radiator 41 through the cooling liquid outlet tube 19b and then again returned to the radiator 41 to be cooled therein.

Thus, the cooling liquid C circulates through the radiator 41 and the cooling plate 8 in this electric motorcar 40 to assuredly cool the semiconductor element 2 for a long period of time, securing high liability of the semiconductor. Furthermore, in electric vehicles such as electric motorcars, since water cooling mechanism is equipped, it is easy to apply a semiconductor module equipping a liquid-cooling type cooling plate according to the present invention.

### EXAMPLE

Semiconductor element mounting substrates 1B and semiconductor modules S2 shown in FIGS. 3 to 7 were manufactured. In the semiconductor element mounting substrates 1B of Examples 1 to 11, the structure of the insulating layer 3 was changed as shown in Table 1 with the conducting layer 4 and the liquid-cooling type cooling plate 8 unchanged.

As the aforementioned conducting layer 4, a copper foil 70 μm thick was used in each Example.

As explained above, in the liquid-cooling type cooling plate 8, a plurality of aluminum multi-bored tubes 20 were accommodated in an aluminum case main body 10 and brazed therein, and the first connecting member 18a and the second connecting member 18b were brazed thereto. In detail, each multi-bored tube 20 was an extruded tube with a height of 1.7 mm and a width of 16 mm having 19 fine passages 21. The equivalent diameter of the fine passage 21 was 0.7 mm, the thickness of the peripheral wall was 0.3 mm, and the thickness of the partition between adjacent passages 21 and 21 was 0.2 mm. In each Example, twelve pieces of the aforementioned multi-bored tubes 20 were arranged. The aforementioned case main body 10 was rectangular in plane shape, 100 mm×200 mm in plane size, 20 mm in height, 2 mm in thickness of the side wall, 2 mm in the depth of the tube accommodating dented portion 12. The aforementioned cover plate 30 was a plate with a thickness of 3 mm. For the illustration purpose, the number of the fine passages of the multi-bored tube was not in agreement with this actual number.

As for the insulating layer 3, in Examples 1 and 2, it was formed only by insulating resin, and in Examples 3 to 6, it was formed by resin composite in which thermally conductive filler was added to insulating resin. In Examples 7 to 11, it was formed by composite material in which glass fiber nonwoven fabric as the insulating cloth was impregnated with insulating resin or insulating resin composite. The type of the insulating resin, the type and content of the thermally conductive filler, the thickness of the insulating cloth, and the thickness of each formed insulating layer used in each Example are shown in Table 1. Each thermal conductivity is also shown.

The aforementioned conducting layer 4, insulating layer 3 and liquid-cooling type cooling plate 8 were pressed under the pressure of 3.92 MPa (40 kgf/cm²) at 170° C. for 2 hours to manufacture a semiconductor element mounting substrate 1B by integrally joining them.

The thermal resistance value of each semiconductor element mounting substrate 1B manufactured as mentioned above is shown in Table 1.

Furthermore, a semiconductor element 2 was soldered to the aforementioned semiconductor element mounting substrate 1B to obtain a semiconductor module S2.

As to the curving of the insulating layer 3 with time, based on JIS C6481, the maximum curved amount D1 and the length L1 of the maximum curved portion were measured, and then the curving rate W1(%)=(D1/L1)×100 was obtained. Based on the curving rate W1 (%), it was evaluated by the following criteria:

⊚: less then 1%

◯: 1 to 2%

x: exceeding 2%

As a Comparative Example, a semiconductor element mounting substrate was manufactured by joining the aforementioned copper foil as the conducting layer to a ceramics insulating layer with a thickness of 3 mm and further joining this ceramics insulating layer to a liquid-cooling type cooling plate 8 using adhesive agent. The thermal conductivity and thermal resistance of this Comparative Example are also shown in Table 1.

TABLE 1

| | Structure of insulating layer | | | | Thermal | | |
|---|---|---|---|---|---|---|---|
| | | | Thickness of | Thickness of | conductivity of | Thermal | Curves of |
| | | Filer and | insulating | insulating | insulating | resistance | insulating |
| | Insulating resin | contents | cloth | layer (μ/m) | layer (W/mK) | (K/W) | layer |
| Example 1 | Epoxy resin | Nil | Nil | 80 | 0.3 | 0.7 | ◯ |
| Example 2 | Polyimide resin | Nil | Nil | 80 | 0.3 | 0.7 | ◯ |
| Example 3 | Epoxy resin | Al₂O₃, 40 Vol % | Nil | 80 | 0.9 | 0.2 | ◯ |
| Example 4 | Epoxy resin | Al₂O₃, 60 Vol % | Nil | 80 | 2 | 0.09 | ◯ |
| Example 5 | Epoxy resin | Al₂O₃, 80 Vol % | Nil | 80 | 8 | 0.022 | ◯ |
| Example 6 | Epoxy resin | Al₂O₃, 90 Vol % | Nil | 80 | 10 | 0.018 | ◯ |
| Example 7 | Epoxy resin | Nil | 40 μm | 40 | 0.3 | 0.7 | ⊚ |
| Example 8 | Epoxy resin | Al₂O₃, 40 Vol % | 40 μm | 40 | 0.9 | 0.45 | ⊚ |
| Example 9 | Epoxy resin | Al₂O₃, 60 Vol % | 40 μm | 40 | 2 | 0.38 | ⊚ |
| Example 10 | Epoxy resin | Al₂O₃, 80 Vol % | 40 μm | 40 | 8 | 0.346 | ⊚ |
| Example 11 | Epoxy resin | Al₂O₃, 90 Vol % | 40 μm | 40 | 10 | 0.343 | ⊚ |

| | | | |
|---|---|---|---|
| Com. Example | Ceramics insulating layer 3 mm thick is adhered to | 30/0.3 | 0.7 |
| | liquid-cooling type cooling plate via adhesive agent | | |

From the results shown in Table 1, it was confirmed that the semiconductor element mounting substrate of each Example could demonstrate outstanding cooling performance. Also confirmed is that the use of insulating resin composite blended with thermally conductive filler as an insulating layer could raise the thermal conductivity and therefore enhance the cooling performance. Moreover, by using an insulating cloth, it was also confirmed that the change in size of the insulating layer can be restrained for a long period of time.

### INDUSTRIAL APPLICABILITY

The semiconductor element mounting substrate according to the present invention can be utilized as a substrate for cooling various heat generating members, such as a semiconductor element for electric vehicles and a semiconductor element for computers.

While the present invention may be embodied in many different forms, a number of illustrative embodiments are described herein with the understanding that the present disclosure is to be considered as providing examples of the principles of the invention and such examples are not intended to limit the invention to preferred embodiments described herein and/or illustrated herein.

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure and during the prosecution of this case, the following abbreviated terminology may be employed: “e.g.” which means “for example;” and “NB” which means “note well.”

1. A semiconductor element mounting substrate for mounting semiconductor elements, comprising:
an insulating layer;
a conductive layer for attaching a semiconductor element, the conductive layer being formed on one surface of the insulating layer; and
a heat releasing device directly secured to the other surface of the insulating layer.

2. The semiconductor element mounting substrate as recited in claim 1, wherein the heat releasing device is a liquid-cooling type cooling plate having a plurality of fine passages through which cooling fluid passes.

3. The semiconductor element mounting substrate as recited in claim 2,
wherein the liquid-cooling type cooling plate is provided with at least one flat multi-bored tube having fine passages for the cooling fluid, a case main body having two header forming dented portions disposed apart from each other, a tube accommodating dented portion for accommodating the tube, and a cover plate to be disposed on the case main body,
wherein the multi-bored tube is pinched by and between the case main body and the cover plate in a state in which the cover plate is disposed on the case main body with the multi-bored tube accommodated in the tube accommodating dented portion in communication with the header forming dented portions, and
wherein openings of both the header forming dented portions are closed by the cover plate, thereby forming two header portions, and
wherein the case main body, the multi-bored tube and the cover plate are integrally secured in a state in which leakage of the cooling fluid passing through the header portions is prevented.

4. The semiconductor element mounting substrate as recited in claim 3, wherein the liquid-cooling type cooling plate is further provided with a first connecting member to be connected to a cooling fluid inlet tube and a second connecting member to be connected to a cooling fluid outlet tube, and wherein the first connecting member is connected to one of the header portions and the second connecting member is connected to the other of the header portions.

5. The semiconductor element mounting substrate as recited in claim 2, wherein an equivalent diameter of the fine passage of the liquid-cooling type cooling plate is set so as to fall within the range of 0.05 to 1.7 mm.

6. The semiconductor element mounting substrate as recited in claim 1, wherein the insulating layer is made of insulating resin.

7. The semiconductor element mounting substrate as recited in claim 1, wherein the insulating layer is made of insulating resin composite in which thermally conductive filler is added to insulating resin.

8. The semiconductor element mounting substrate as recited in claim 1, wherein the insulating layer is a composite member that an insulating cloth is impregnated with insulating resin or insulating resin composite in which thermally conductive filler is added to insulating resin.

9. The semiconductor element mounting substrate as recited in claim 6, wherein the insulating resin is at least one of epoxy resin and polyimide resin.

10. The semiconductor element mounting substrate as recited in claim 7, wherein the insulating resin is at least one of epoxy resin and polyimide resin.

11. The semiconductor element mounting substrate as recited in claim 8, wherein the insulating resin is at least one of epoxy resin and polyimide resin.

12. The semiconductor element mounting substrate as recited in claim 7 or 8, wherein the thermally conductive filler is at least one of SiO₂, Al₂O₃, BeO, MgO, Si₃N₄ and BN.

13. The semiconductor element mounting substrate as recited in claim 7 or 8, wherein a content of the thermally conductive filler in the insulating resin composite is 40 to 90 Vol %.

14. A semiconductor module, comprising:
a semiconductor element mounting substrate for mounting semiconductor elements, wherein the semiconductor element mounting substrate includes an insulating layer, a conductive layer for attaching a semiconductor element, the conductive layer being formed on one surface of the insulating layer, and a heat releasing device directly secured to the other surface of the insulating layer; and
a semiconductor element attached to the conductive layer.

15. The semiconductor module as recited in claim 14, wherein the heat releasing device is a liquid-cooling type cooling plate having a plurality of fine passages for cooling fluid.

16. The semiconductor module as recited in claim 15,
wherein the liquid-cooling type cooling plate is provided with at least one flat multi-bored tube having fine passages for the cooling fluid, a case main body having two header forming dented portions disposed apart from each other, a tube accommodating dented portion for accommodating the tube, and a cover plate to be disposed on the case main body,
wherein the multi-bored tube is pinched by and between the case main body and the cover plate in a state in which the cover plate is disposed on the case main body with the multi-bored tube accommodated in the tube accommodating dented portion in communication with the header forming dented portions, and
wherein openings of both the header forming dented portions are closed by the cover plate, thereby forming two header portions, and
wherein the case main body, the multi-bored tube and the cover plate are integrally secured in a state in which leakage of the cooling fluid passing through the header portions is prevented.

17. An electric vehicle equipped with a semiconductor module, wherein the semiconductor module includes a semiconductor element mounting substrate for mounting semiconductor elements, the semiconductor element mounting substrate being provided with an insulating layer, a conductive layer for attaching a semiconductor element, the conductive layer being formed on one surface of the insulating layer, and a heat releasing device directly secured to the other surface of the insulating layer, and a semiconductor element attached to the conductive layer.

18. The electric vehicle as recited in claim 17, wherein the heat releasing device of the semiconductor element mounting substrate is a liquid-cooling type cooling plate having a plurality of fine passages for cooling fluid.

19. The electric vehicle as recited in claim 18, wherein the electric vehicle is further equipped with a radiator, wherein cooling liquid cooled by the radiator is introduced into the cooling plate, and the cooling liquid flowed out of the liquid-cooling type cooling plate is cooled by the radiator.
